(19) United States
(12) Patent Application Publication
(10) Pub. No.: US 2025/0311384 A1
(43) Pub. Date: Oct. 2, 2025

(54) SELF-ALIGNED CONTACT FORMATION ON SOURCE/DRAIN

(71) Applicant: Tokyo Electron Limited, Tokyo (JP)

(72) Inventors: Eric Chih-Fang LIU, Albany, NY (US); Kangyi LIN, Albany, NY (US)

(73) Assignee: Tokyo Electron Limited, Tokyo (JP)

(21) Appl. No.: 18/620,549

(22) Filed: Mar. 28, 2024

(51) Int. Cl. H01L 21/8234; H01L 27/088; H01L 29/66

(52) U.S. Cl. CPC H10D 84/038; H10D 64/017; H10D 84/0151; H10D 84/83

(57) ABSTRACT

A semiconductor device is provided. The semiconductor device includes first transistors positioned over a substrate and arranged along a first row in a first direction substantially parallel to a working surface of the substrate. Second transistors are positioned over the substrate and arranged along a second row in the first direction. Each first transistor is aligned with a respective second transistor in a second direction substantially parallel to the working surface of the substrate. An isolation wall structure is positioned between the first transistors and the second transistors.

### FIELD OF THE INVENTION

This disclosure relates to microelectronic devices including semiconductor devices, transistors, and integrated circuits, and methods of microfabrication.

### BACKGROUND

In the manufacture of a semiconductor device (especially on the microscopic scale), various fabrication processes are executed such as film-forming depositions, etch mask creation, patterning, material etching and removal, and doping treatments. These processes are performed repeatedly to form desired semiconductor device elements on a substrate. Historically, with microfabrication, transistors have been created in one plane, with wiring/metallization formed above the active device plane, and have thus been characterized as two-dimensional (2D) circuits or 2D fabrication. Scaling efforts have greatly increased the number of transistors per unit area in 2D circuits, yet scaling efforts are running into greater challenges as scaling enters single digit nanometer semiconductor device fabrication nodes. Semiconductor device fabricators have expressed a desire for three-dimensional (3D) semiconductor circuits in which transistors are stacked on top of each other.

### SUMMARY

The present disclosure relates to a semiconductor device and a method of forming the same.

According to a first aspect of the disclosure, a semiconductor device is provided. The semiconductor device includes first transistors positioned over a substrate and arranged along a first row in a first direction substantially parallel to a working surface of the substrate.

Second transistors are positioned over the substrate and arranged along a second row in the first direction. Each first transistor is aligned with a respective second transistor in a second direction substantially parallel to the working surface of the substrate. An isolation wall structure is positioned between the first transistors and the second transistors.

In some embodiments, the isolation wall structure includes slab structures and block structures arranged alternatingly along the first direction. The slab structures are thinner than the block structures in the second direction.

In some embodiments, the slab structures consist of a first dielectric material.

In some embodiments, a second dielectric material is formed on opposing sides of each of the slab structures as well as formed between gate contact structures of the first transistors and source/drain (S/D) contact structures of the first transistors.

In some embodiments, a sidewall structure consists of the first dielectric material and is positioned parallel to and away from the slab structures.

In some embodiments, the slab structures are co-planar.

In some embodiments, the slab structures are positioned between source/drain (S/D) structures of the first transistors and the second transistors. The block structures are positioned between gate structures of the first transistors and the second transistors.

In some embodiments, the isolation wall structure consists of a dielectric material in a cross section substantially perpendicular to the working surface of the substrate.

In some embodiments, the isolation wall structure is continuous and seamless in the cross section.

In some embodiments, the cross section is substantially parallel to the first direction.

According to a second aspect of the disclosure, a method of manufacturing a semiconductor device is provided. The method includes forming first transistors over a substrate. The first transistors are arranged along a first row in a first direction substantially parallel to a working surface of the substrate. Second transistors are formed over the substrate. The second transistors are arranged along a second row in the first direction. Each first transistor is aligned with a respective second transistor in a second direction substantially parallel to the working surface of the substrate. An isolation wall structure is formed between the first transistors and the second transistors.

In some embodiments, a row of transistors are formed over the substrate. The row of transistors are arranged in the first direction. An opening is formed to divide the row of transistors into the first transistors and the second transistors. The isolation wall structure is formed in the opening.

In some embodiments, the row of transistors include channel structures, source/drain (S/D) structures and gate structures. An etch stop layer is formed along sidewalls of the gate structure and on top surfaces of the S/D structures. Remaining space of the etch stop layer is filled with a dielectric material.

In some embodiments, the dielectric material is removed to expose the etch stop layer. The etch stop layer is directionally etched to expose the top surfaces of the S/D structures.

In some embodiments, S/D contact structures are formed over the S/D structures.

In some embodiments, fin structures are formed over the substrate. The fin structures are spaced apart from each other in the first direction and include channel structures and dummy gate structures. A dielectric material is formed over the fin structures.

In some embodiments, a protective structure is formed over the fin structures in a first region while leaving the fin structures exposed in a second region. A dielectric film is isotropically formed over the protective structure in the first region and the fin structures in the second region. The dielectric film includes vertical portions on sidewalls of the protective structure. The dielectric film is directionally etched so that remaining vertical portions of the dielectric film include slab structures substantially perpendicular to the working surface of the substrate.

In some embodiments, the dummy gate structures are replaced with gate structures. Block structures are formed to divide the gate structures into first gate structures in the first row and second gate structures in the second row. The slab structures and the block structures are arranged alternatingly along the first direction. The slab structures are thinner than the block structures in the second direction.

In some embodiments, the method further includes directionally etching to expose top surfaces of the S/D structures. S/D contact structures are formed over the S/D structures.

In some embodiments, the dielectric material is formed on opposing sides of the slab structures.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be increased or reduced for clarity of discussion.

FIG. 1 shows a perspective view of a semiconductor device in accordance with some embodiments of the present disclosure.

FIG. 2A shows a perspective view of a semiconductor device in accordance with some embodiments of the present disclosure.

FIG. 2B shows a vertical cross-sectional view taken along the line cut AA′ in FIG. 2A in accordance with some embodiments of the present disclosure.

FIG. 3 shows a block diagram of a process for manufacturing a semiconductor device, in accordance with some embodiments of the present disclosure.

FIGS. 4, 5, 6, 7, 8 and 9 show vertical cross-sectional views of a semiconductor device at various intermediate steps of manufacturing, in accordance with some embodiments of the present disclosure.

FIG. 10 shows a block diagram of a process for manufacturing a semiconductor device, in accordance with some embodiments of the present disclosure.

FIGS. 11, 12, 13, 14, 15, 16, 17, 18, 19, 20 and 21 show vertical cross-sectional views of a semiconductor device at various intermediate steps of manufacturing, in accordance with some embodiments of the present disclosure.

FIG. 15B shows a vertical cross-sectional view taken along the line cut BB′ in FIG. 15 in accordance with one embodiment of the present disclosure.

FIG. 18B shows a vertical cross-sectional view taken along the line cut DD′ in FIG. 18 in accordance with one embodiment of the present disclosure.

FIG. 22 shows a flow chart of a process for manufacturing a semiconductor device, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity's sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

In the drawings, like reference numerals designate identical or corresponding parts throughout the several views. Additionally, as used herein, the words “a”, “an” and the like generally carry a meaning of “one or more”, unless stated otherwise.

Furthermore, the terms, “approximately”, “approximate”, “about” and similar terms generally refer to ranges that include the identified value within a margin of 20%, 10%, or preferably 5%, and any values therebetween.

3D integration, i.e. the vertical stacking of multiple devices, aims to overcome scaling limitations experienced in planar devices by increasing transistor density in volume rather than area. Although device stacking has been successfully demonstrated and implemented by the flash memory industry with the adoption of 3D NAND, application to random logic designs is substantially more difficult. 3D integration for logic chips (CPU (central processing unit), GPU (graphics processing unit), FPGA (field programmable gate array, SoC (System on a chip)) is being pursued.

In conventional technology, gate spacer lowering during a self-aligned contact formation process can induce the gate to short-circuit the source/drain (S/D). There is no edge placement error (EPE) control in one lateral direction (e.g. the Y direction) and poor EPE control in the other lateral direction (e.g. the X direction). Contact area is often small and limited.

Techniques herein employ a self-aligned contact (SAC) formation strategy compared to traditional processes by combining the gate cut process and the zeroth interlayer dielectric (ILDO) replacement to confine the SAC process in both lateral directions, thus improving EPE control and reducing the loss of gate spacer/gate height. Specifically, additional designed patterns can be added to the gate cut mask, therefore resulting in an “elongation” gate cut pattern. Anisotropic etch of the gate cut in various materials can be performed. ILDO replacement can be utilized to replace the original ILDO with other materials. Chemical etch of interlayer dielectric (ILD) to spacer material can be achieved with an ultra-high etching selectivity. SAC can be formed in both lateral directions without the risk of spacer lowering.

Techniques herein can fundamentally resolve the spacer lowering issue during the SAC process. Good EPE control in contact formation is enabled in both lateral directions. The risk of short-circuiting contact structures from the narrowing isolation along the gate direction is minimized. Gate height can be retained because of less gate height loss during the process. One photo layer is potentially reduced by combining the patterns into the gate cut mask. The processing window of the isolation gap filling process can be enhanced when the conventional small cut is replaced with a big cut herein. Therefore, the contact area is enlarged, thus reducing contact resistance.

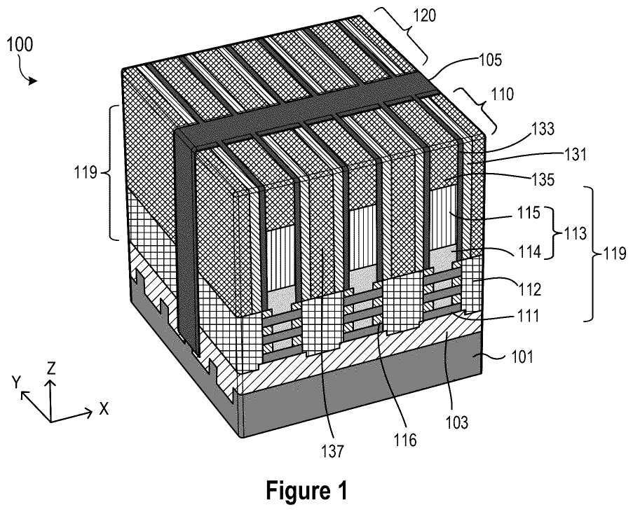

FIG. 1 shows a perspective view of a semiconductor device 100 in accordance with some embodiments of the present disclosure. As shown, the semiconductor device 100 includes transistors 119 positioned over a substrate 101. The transistors 119 can be arranged along a first row 110 in the X direction as well as arranged along a second row 120 in the X direction. Each of the transistors 119 in the first row 110 (also referred to as a first transistor) is aligned in the Y direction with a respective one of the transistors 119 in the second row 120 (also referred to as a second transistor). The semiconductor device 100 further includes an isolation wall structure 105 positioned between the first row 110 and the second row 120 so that the first transistor and the second transistor are separated from each other.

In some embodiments, the isolation wall structure 105 consists of a dielectric material, or rather a single dielectric material. Therefore, in an XZ cross section, the isolation wall structure 105 is continuous and seamless. By contrast in conventional technology, a corresponding isolation structure between two neighboring rows of transistors typically includes several materials in a cross section parallel to the two neighboring rows and are thus not seamless.

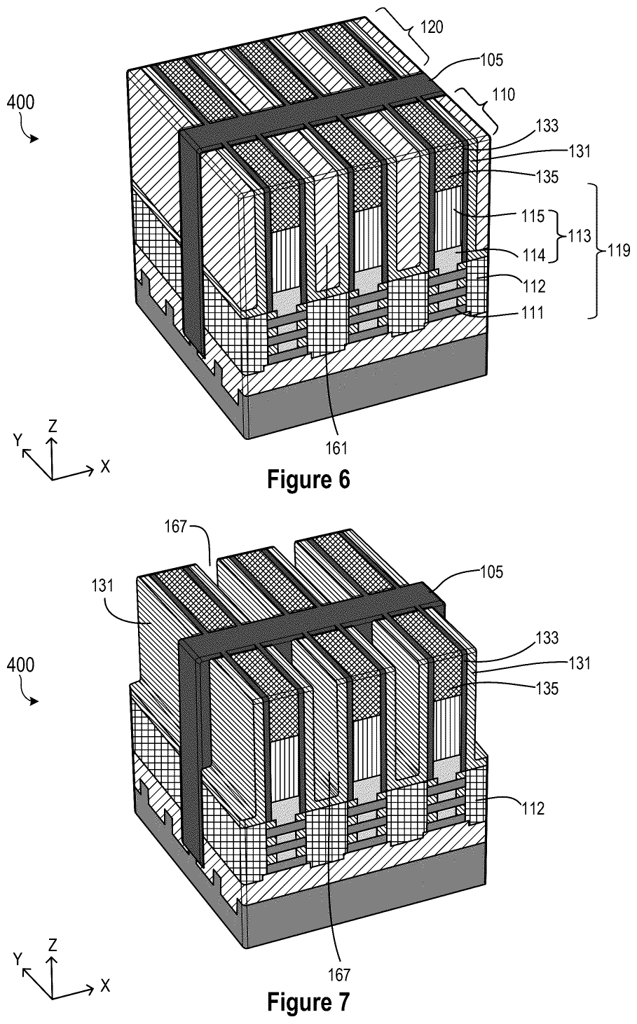

In the example of FIG. 1, the isolation wall structure 105 essentially fills a trench space between the first row 110 and the second row 120. It should be understood that the isolation wall structure 105 may consist of a plurality of dielectric films sequentially formed along the contour of the trench space in other examples, as will be further explained later in FIGS. 5 and 6.

The transistors 119 can each include one or more (e.g. three) channel structures 111, S/D structures 112 and a gate structure 113. In this embodiment, the S/D structures 112 are in direct contact with the channel structures 111 on opposing ends so each of the S/D structures 112 is configured to function as a common S/D structure for two neighboring ones of the transistors 119. The gate structure 113 is in direct contact with the channel structures 111 and configured to function as a common gate structure for the channel structures 111 within each of the transistors 119. As a result, the transistors 119 can each be configured to function as a gate-all-around (GAA) multi-channel transistor. The semiconductor device 100 can further include a gate contact structure 135 and an S/D contact structure 137 coupled to the gate structure 113 and the S/D structures 112 respectively.

In some embodiments, the gate structure 113 includes a gate dielectric 114 (such as a high-k dielectric) and a gate metal 115 (such as a work function metal (WFM)). While the gate metal 115 is shown as a single material, the gate metal 115 may be made up of two or more layers of metals having different work functions. Similarly, the gate dielectric 114 may be made up of two or more layers of dielectric materials. Additionally, inner spacers 116 can be disposed on ends of the gate dielectric 114. The inner spacers 116 are insulating and therefore can separate the gate structure 113 from the S/D structures 112.

In some embodiments, the semiconductor device 100 can include dielectric materials, e.g. as shown by 103, 105, 114, 131 and 133. The dielectric materials may also be referred to as isolation structures, isolation layers, diffusion breaks, inner spacers, gate dielectrics, capping layers, etc. depending on functions thereof. The dielectric materials may include identical materials or may include different materials from each other. For example, the dielectric material 133 and the isolation wall structure 105 may include a same material or different materials.

In some embodiments, two channel structures can include different chemical compositions from one another. That is, the channel structures 111 can include different semiconductor materials, different dopants and/or different dopant concentration profiles from each other. Additionally, the channel structures 111 can have various shapes or geometry. For example, the channel structures 111 can be nanosheets.

Further, it should be understood that the semiconductor device 100 can include any number of rows (e.g. 110, 120 and the like) arranged in the Y direction. Each pair of neighboring rows can be separated by a respective isolation wall structure (e.g. 105 and the like). Each row (e.g. 110, 120 and the like) can include any number of transistors (e.g. 119 and the like) arranged in the X direction. Respective transistors of different rows can be aligned in the Y direction. Each transistor may include any number of channel structures arranged in the Z direction, while respective S/D regions and gate structures can be configured to electrically connect to any number of channel structures.

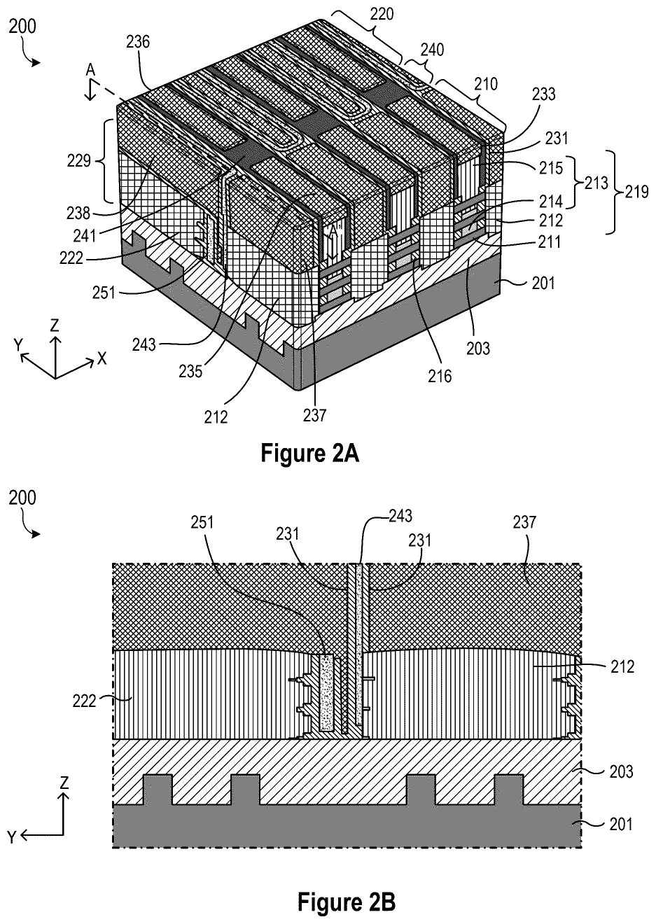

FIG. 2A shows a perspective view of a semiconductor device 200, and FIG. 2B shows a vertical cross-sectional view of the semiconductor device 200 taken along the line cut AA′ in FIG. 2A in accordance with some embodiments of the present disclosure. As shown, the semiconductor device 200 includes first transistors 219 positioned over a substrate 201 and arranged along a first row 210 in the X direction. The semiconductor device 200 also includes second transistors 229 positioned over the substrate 201 and arranged along a second row 220 in the X direction. Each of the first transistors 219 is aligned with a respective one of the second transistors 229 in the Y direction. The semiconductor device 200 further includes an isolation wall structure 240 positioned between the first transistors 219 and the second transistors 229, or on a boundary between the first row 210 and the second row 220.

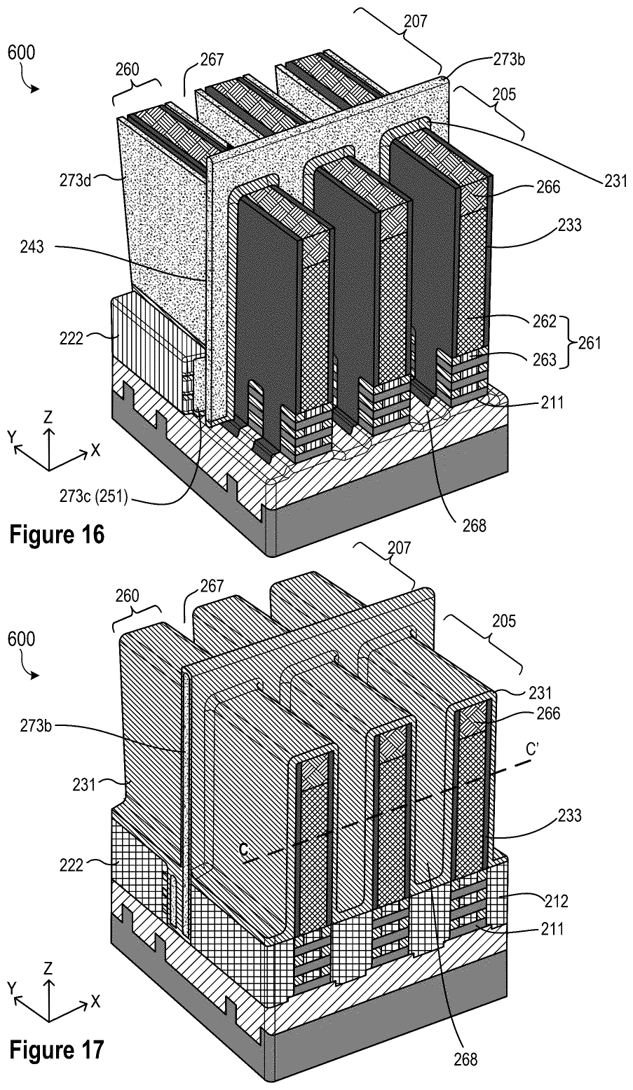

In some embodiments, the isolation wall structure 240 can include slab structures 243 and block structures 241 arranged alternatingly along the X direction. The slab structures 243 may be thinner than the block structures 241 in the Y direction. The slab structures 243 may consist of a single dielectric material. A dielectric material 231 can be formed on opposing sides of each of the slab structures 243. In other words, the slab structures 243 can each be sandwiched between the dielectric material 231 in the Y direction. As will be further explained in FIGS. 16-18, the slab structures 243 can be co-planar, that is, positioned on a same plane.

In some embodiments, the first transistors 219 each include one or more (e.g. three) first channel structures 211, first S/D structures 212 and a first gate structure 213. Herein, the first S/D structures 212 are in direct contact with the first channel structures 211 on opposing ends so each of the first S/D structures 212 is configured to function as a common S/D region for two neighboring ones of the first transistors 219. The first gate structure 213 is in direct contact with the first channel structures 211 and configured to function as a common gate structure for the first channel structures 211 within each of the first transistors 219. As a result, the first transistors 219 can each be configured to function as a gate-all-around (GAA) multi-channel transistor. The semiconductor device 200 can further include a first gate contact structure 235 and a first S/D contact structure 237 coupled to the first gate structure 213 and the first S/D structures 212 respectively.

While not all explicitly shown, the second transistors 229 can be similar to the first transistors 219 as one skilled in the art would understand. For example, the second transistors 229 can each include one or more (e.g. three) second channel structures, second S/D structures 222 and a second gate structure that respectively correspond to the first channel structures 211, the first S/D structures 212 and the first gate structure 213. Similar descriptions have been provided and will be omitted herein for simplicity purposes. Additionally, the semiconductor device 200 can further include a second gate contact structure 236 and a second S/D contact structure 238 coupled to the second gate structure and the second S/D structures 222 respectively.

As illustrated, the slab structures 243 can be positioned between the first S/D structures 212 and the second S/D structures 222 as well as between the first S/D contact structure 237 and the second S/D contact structure 238. Similarly, the block structures 241 can be positioned between the first gate structure 213 and the second gate structure (not shown) of the second transistors 229 as well as between the first gate contact structure 235 and the second gate contact structure 236. Therefore, the isolation wall structure 240, which includes the slab structures 243 and the block structures 241 arranged alternatingly along the X direction, can separate the first transistors 219 in the first row 210 from the second transistors 229 in the second row 220.

In some embodiments, the semiconductor device 200 can further include a sidewall structure 251 consisting of a same dielectric material as the slab structures 243. The sidewall structure 251 can be positioned along a sidewall of the second S/D structures 222 and parallel to and away from the slab structures 243.

In some embodiments, the first gate structure 213 each include a gate dielectric 214, (such as a high-k dielectric) and a gate metal 215 (such as a work function metal (WFM)). While the gate metal 115 is shown as a single material, the gate metal 115 may be made up of two or more layers of metals having different work functions. Similarly, the gate dielectric 114 may be made up of two or more layers of dielectric materials. Additionally, inner spacers 216 can be disposed on ends of the first gate structure 213. The inner spacers 216 are insulating and therefore can separate the first gate structure 213 from the first S/D structures 212.

In some embodiments, the semiconductor device 200 can include dielectric materials, e.g. as shown by 203, 214, 231, 233, 241, 243 and 251. The dielectric materials may also be referred to as isolation structures, isolation layers, diffusion breaks, inner spacers, gate dielectrics, capping layers, etc. depending on functions thereof. Some of the dielectric materials may include identical materials or may include different materials from each other. For example, the dielectric material 233 and the block structures 241 may include a same material as each other or different materials from each other. The slab structures 243 and the block structures 241 may include a same material as each other or different materials from each other.

In some embodiments, two channel structures can include different chemical compositions from one another. That is, channel structures can include different semiconductor materials, different dopants and/or different dopant concentration profiles from each other.

Further, it should be understood that the semiconductor device 200 can include any number of rows (e.g. 210, 220 and the like) arranged in the Y direction. Each pair of neighboring rows can be separated by a respective isolation wall structure (e.g. 240 and the like). Each row (e.g. 210, 220 and the like) can include any number of transistors (e.g. 219, 229 and the like) arranged in the X direction. Respective transistors of different rows can be aligned in the Y direction. Each transistor may include any number of channel structures arranged in the Z direction, while respective S/D regions and gate structures can be configured to electrically connect to any number of channel structures.

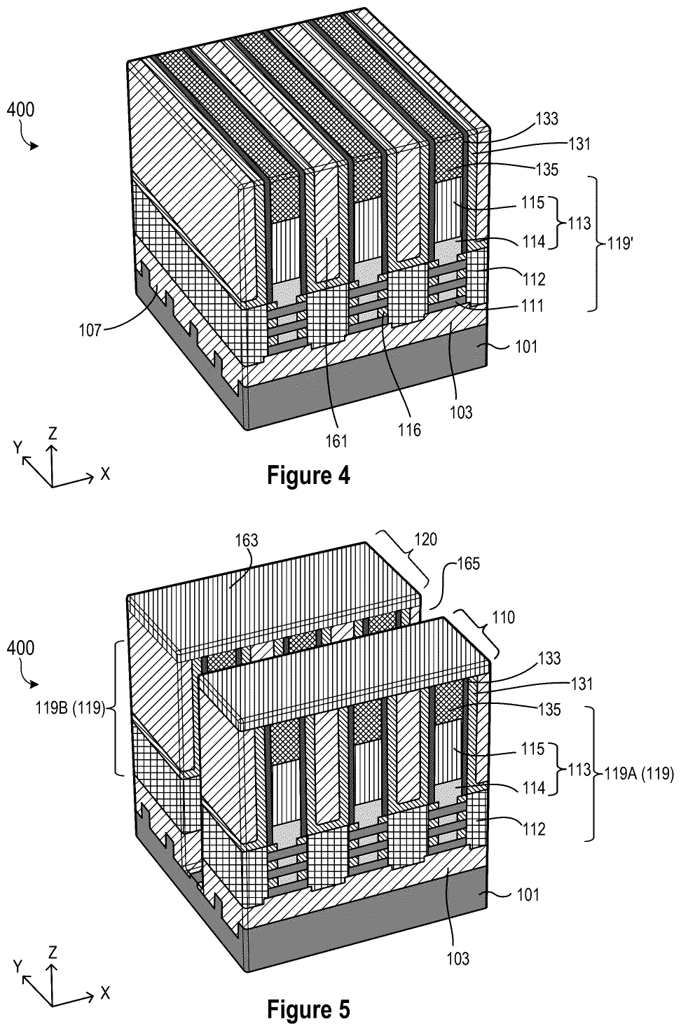

FIGS. 4, 5, 6, 7, 8 and 9 show vertical cross-sectional views of a semiconductor device 400 at various intermediate steps of manufacturing, in accordance with some embodiments of the present disclosure.

As shown in FIG. 4, the semiconductor device 400 includes the substrate 101. A row of transistors 119′ are formed over the substrate 101 and arranged in the X direction. Note that similar or identical components are labeled with similar or identical numerals in the present disclosure unless specified otherwise. Similar descriptions have been provided and will be omitted for simplicity purposes. In particular, the dielectric material 133 can be formed along sidewalls of the gate structure 113 and on top surfaces of the S/D structures 112. Remaining space of the dielectric material 133 is filled with a dielectric material 161.

In a non-limiting example, the substrate 101 includes silicon. The dielectric material 103 includes silicon oxide. The dielectric material 131 includes silicon nitride. The dielectric material 133 includes silicon oxynitride, silicon carbon nitride and/or silicoboron-carbonitride. The dielectric material 161 includes silicon oxide. The gate contact structure 135 includes tungsten. The channel structures 111 include silicon. The S/D structures 112 include silicon, germanium or silicon-germanium. The gate dielectric 114 includes a high-k dielectric. The gate metal 115 includes a work function metal.

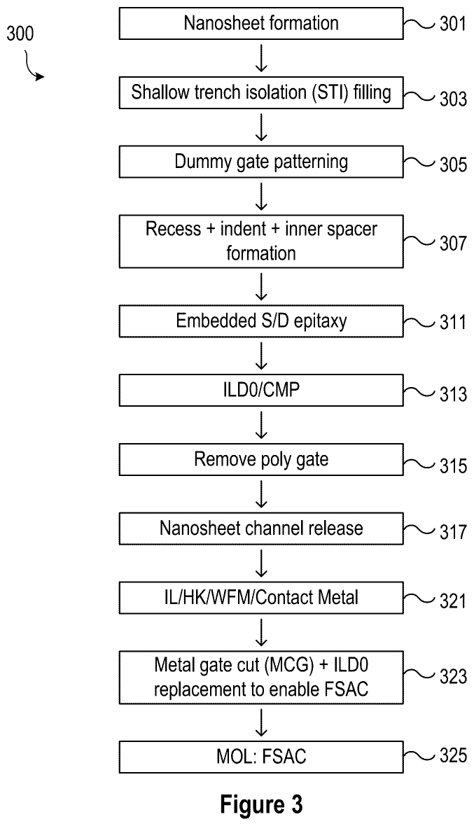

In some embodiments, the row of transistors 119′ can be formed by a process 300 in FIG. 3. In block 301, nanosheets (e.g. 111) are formed and will be used as channel structures. In block 303, shallow trench isolation (STI) can be performed to form shallow trenches 107 and filled with the dielectric material 103. In block 305, dummy gates (not shown) are formed. In block 307, the inner spacers 116 are formed in indents formed by recessing the dummy gates as a skilled artisan would understand. In block 311, embedded source/drain (S/D) epitaxy is performed to form the S/D structures 112. In block 313, the zeroth interlayer dielectric (ILDO) is deposited and planarized by chemical-mechanical polishing (CMP). In block 315, dummy gates such as polysilicon gates are removed. In block 317, nanosheet channels are released. In block 321, the gate dielectric 114 (e.g. a high-k dielectric) and the gate metal 115 (e.g. a work function metal (WFM)) are formed, and at least one contact metal is deposited to form metal contacts. In block 323, a metal gate cut is performed, and the ILDO is replaced to allow for fully self-aligned contact (FSAC). In block 325, FSAC is formed, as will be further explained in FIGS. 5-9.

In FIG. 5, an opening 165 is formed to divide the row of transistors 119′ into the first row 110 and the second row 120. As a result, the transistors 119 are formed. Hereinafter, the transistors 119 in the first row 110 will be referred to as first transistors 119A while the transistors 119 in the second row 120 will be referred to as second transistors 119B.

In some embodiments, a hardmask layer 163 can be formed over the row of transistors 119′. The hardmask layer 163 can include silicon nitride and/or amorphous silicon for example. A photoresist layer (not shown) can then be used to etch the hardmask layer 163 to define an isolation wall pattern in the hardmask layer 163. Subsequently, the hardmask layer 163 is used as an etching mask to etch the row of transistors 119′ so that the isolation wall pattern is transferred to the row of transistors 119′ to form the opening 165. The opening 165 extends through the row of transistors 119′ and may further extend through the dielectric material 103 to expose the substrate 101.

In FIG. 6, the isolation wall structure 105 is formed in the opening 165. In one embodiment, a single dielectric material (e.g. silicon nitride or silicon oxycarbonitride) is deposited to fill the opening 165 and may over-fill to form an overburden on the hardmask layer 163. An etching or CMP process can be executed to remove excessive dielectric material. Compared with conventional technology, the opening 165 herein offers an improved gap filling window. In another embodiment, a plurality of dielectric materials may be formed sequentially in the opening 165. For instance, semi-conformal or conformal dielectric films can be formed to fill the opening 165 so the isolation wall structure 105 includes a plurality of dielectric materials.

In FIG. 7, the dielectric material 161 can be isotropically removed by a selective etching process using the dielectric material 131 as an etch stop layer. As a result, openings 167 are formed, and the dielectric material 131 is exposed. Note that the S/D structures 112 are still covered by the dielectric material 131.

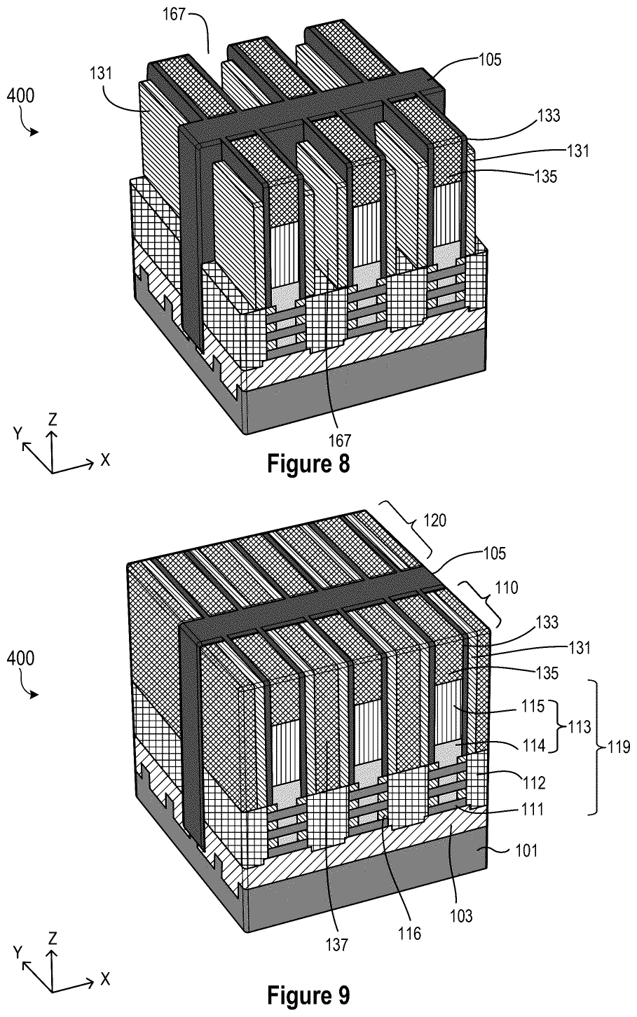

In FIG. 8, a directional etching process (e.g. in the Z direction) is executed to expose top surfaces of the S/D structures 112 by removing part of the dielectric material 131.

In FIG. 9, the S/D contact structure 137 is formed above the S/D structures 112. For instance, a metal such as tungsten or cobalt can be deposited in the openings 167. The metal may overfill the openings 167 and be planarized by CMP. As shown, part of the gate contact structure 135 can be removed by CMP as well. Consequently, the semiconductor device 400 herein has become the semiconductor device 100 in FIG. 1.

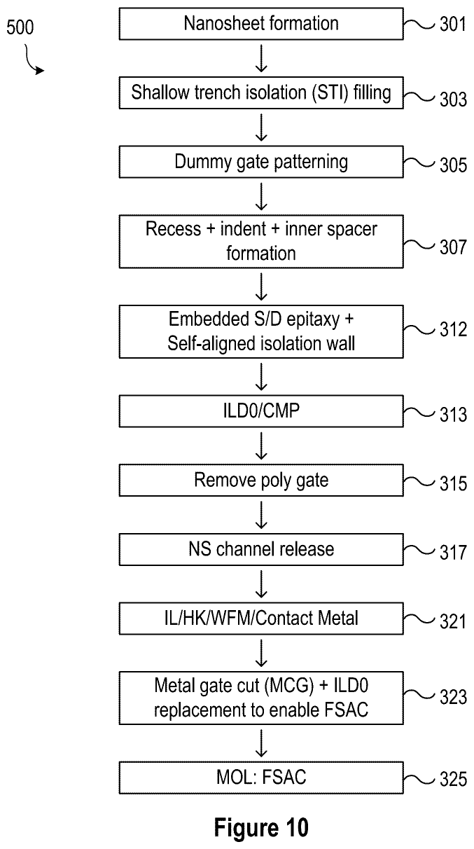

FIG. 10 shows a block diagram of a process 500 for manufacturing a semiconductor device (e.g. 200 and the like), in accordance with some embodiments of the present disclosure. The embodiment of the process 500 is similar to the embodiment of the process 300. Similar or identical components are labeled with similar or identical numerals unless specified otherwise. Descriptions have been provided above and will be omitted for simplicity purposes. Particularly in block 312, embedded source/drain (S/D) epitaxy is performed, and a self-aligned isolation wall is formed.

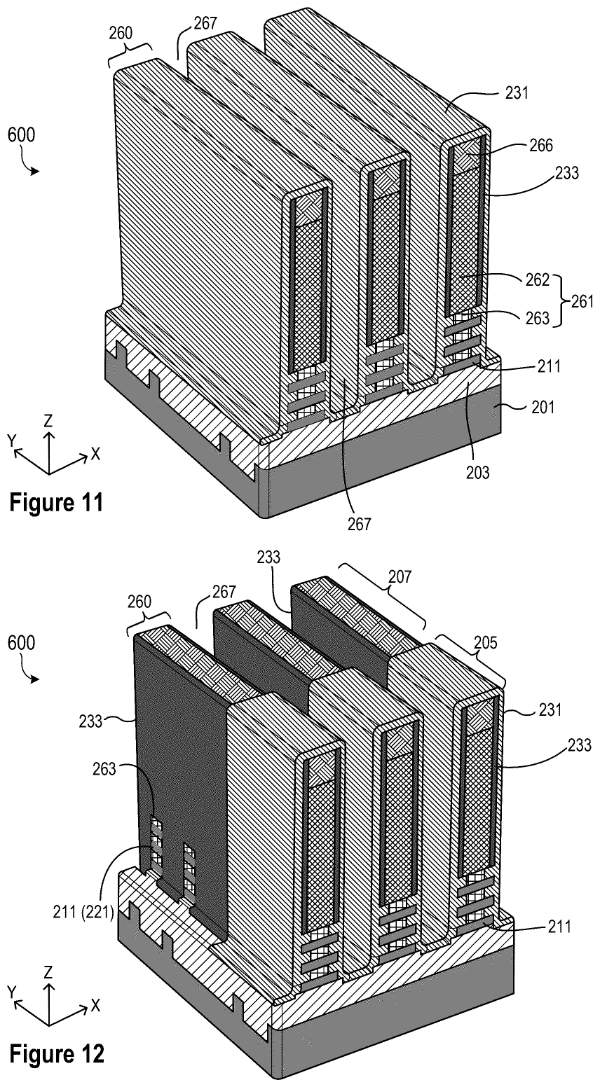

The process 500 in FIG. 10 will be further explained by FIGS. 11, 12, 13, 14, 15, 16, 17, 18, 19, 20 and 21 that show vertical cross-sectional views of a semiconductor device 600 at various intermediate steps of manufacturing, in accordance with some embodiments of the present disclosure.

As illustrated in FIG. 11, the semiconductor device 600 includes the substrate 201. Fin structures 260 are formed over the substrate 201. The fin structures 260 are spaced apart from each other in the X direction and include the first channel structures 211 and dummy gate structures 261. The dielectric material 233 is formed on sidewalls of the dummy gate structures 261. The dielectric material 231 can be formed over the fin structures 260. A dielectric material 266 can be formed over the dummy gate structures 261. In some embodiments, the dielectric material 266 and the dielectric material 233 include a same material and are integrally formed.

In a non-limiting example, the substrate 201 includes silicon. The dielectric material 203 includes silicon oxide. The first channel structures 211 include silicon. The dielectric material 231 includes silicon nitride. The dielectric material 233 includes silicon oxynitride, silicon carbon nitride and/or silicoboron-carbonitride. The dielectric material 266 includes silicon oxynitride, silicon carbon nitride and/or silicoboron-carbonitride. Sacrificial gate layers 262 and 263 include polysilicon and/or silicon oxide.

In FIG. 12, the dielectric material 231 is etched with a mask such as a photoresist layer (not shown). As a result, the dielectric material 231 remains in a first region 205 and is removed from a second region 207. The dielectric material 233 is thus exposed in the second region 207. Moreover, ends of the first channel structures 211 are exposed. Hereinafter, part of the first channel structures 211 in the second region 207 will be referred to as the second channel structures 221.

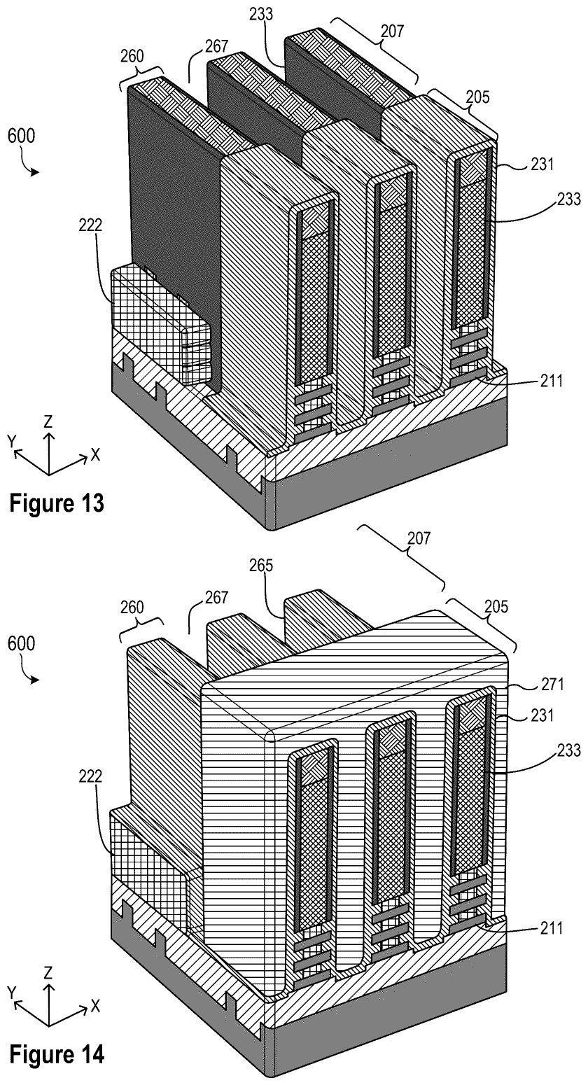

In FIG. 13, the second S/D structures 222 are formed on exposed ends of the second channel structures 221 for example by epitaxial growth from the second channels structures 221.

In FIG. 14, the dielectric material 231 can be deposited over the second S/D structures 222 and the dielectric material 233. A protective structure 271 is formed over the fin structures 260 in the first region 205 while leaving the fin structures 260 exposed in the second region 207. For instance, the protective structure 271 can be a photoresist layer patterned by a photomask.

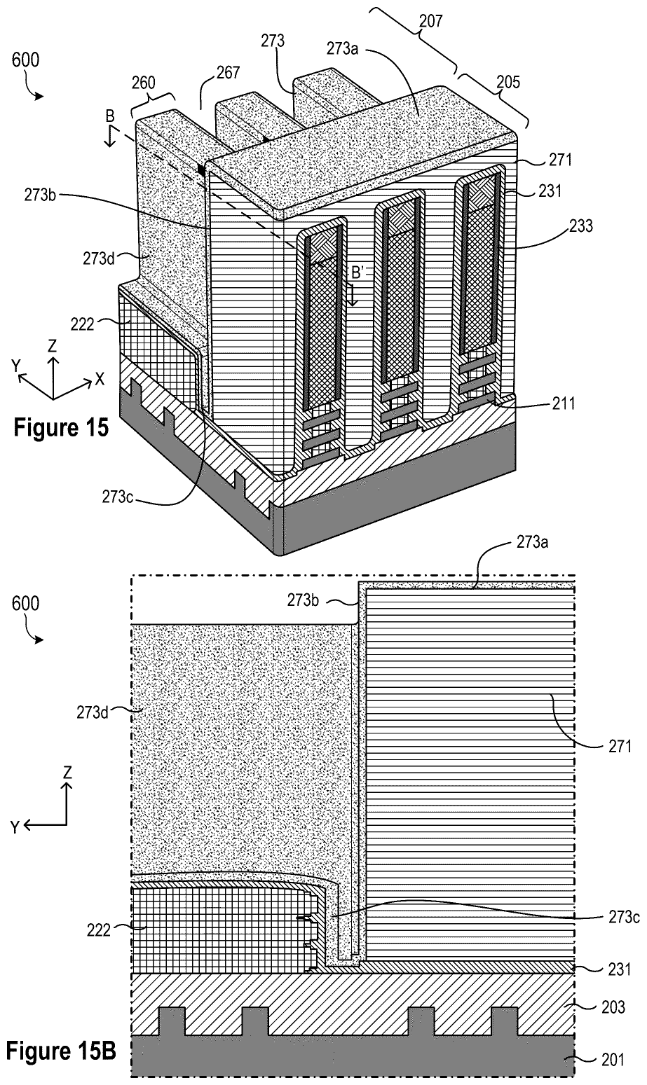

FIG. 15B shows a vertical cross-sectional view taken along the line cut BB′ in FIG. 15 in accordance with one embodiment of the present disclosure. As illustrated, a dielectric film 273 can be isotropically (or conformally, or semi-conformally) formed over the protective structure 271 in the first region 205 and the fin structures 260 in the second region 207. The dielectric film 273 can include horizontal portions such as a horizontal portion 273a on top of the protective structure 271. The dielectric film 273 can also include vertical portions such as a first vertical portion 273b on a sidewall of the protective structure 271, a second vertical portion 273c on a sidewall of the second S/D structures 222, and a third vertical portion 273d on a sidewall of the fin structures 260.

In FIG. 16, the dielectric film 273 can be directionally etched (e.g. in the Z direction) so that the horizontal portions (e.g. 273a) are removed while the vertical portions will mostly remain (partially etched). For instance, a plasma can be oriented in the Z direction to etch the dielectric film 273. Additionally, the protective structure 271 is removed, and then the dielectric material 233 is directionally and selectively etched to form openings 268 that expose ends of the first channels structures 211.

As shown, the first vertical portion 273b, the second vertical portion 273c and the third vertical portion 273d are only slightly (or negligibly) etched in the Z direction. Particularly, the first vertical portion 273b has a shape of a sheet or nanosheet penetrated by the fin structures 260, and the first vertical portion 273b will be used to form slab structures. Remaining part of the second vertical portion 273c forms the sidewall structure 251.

In FIG. 17, the first S/D structures 212 are formed on the ends of the first channels structures 211 for instance by epitaxial growth from the first channels structures 211. Subsequently, the dielectric material 231 (e.g. silicon nitride) can be deposited isotropically (or conformally, or semi-conformally). As a result, the dielectric material 231 can be formed on opposing sides of the first vertical portion 273b.

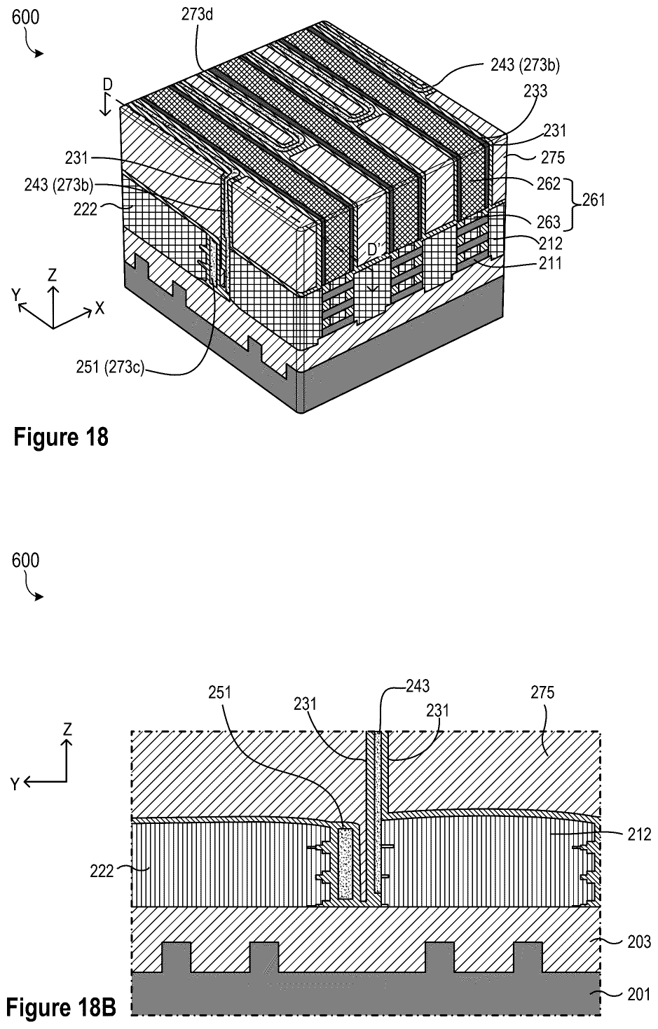

FIG. 18B shows a vertical cross-sectional view taken along the line cut DD′ in FIG. 18 in accordance with one embodiment of the present disclosure. As illustrated, a dielectric material 275 (e.g. silicon oxide) is deposited to fill the openings 267 and 268. The semiconductor device 400 can then be etched down or planarized for instance by CMP to a level represented by the line CC′. As a result, remaining part of the first vertical portion 273b forms the slab structures 243. The slab structures 243 can be co-planar since the slab structures 243 are formed from the first vertical portion 273b.

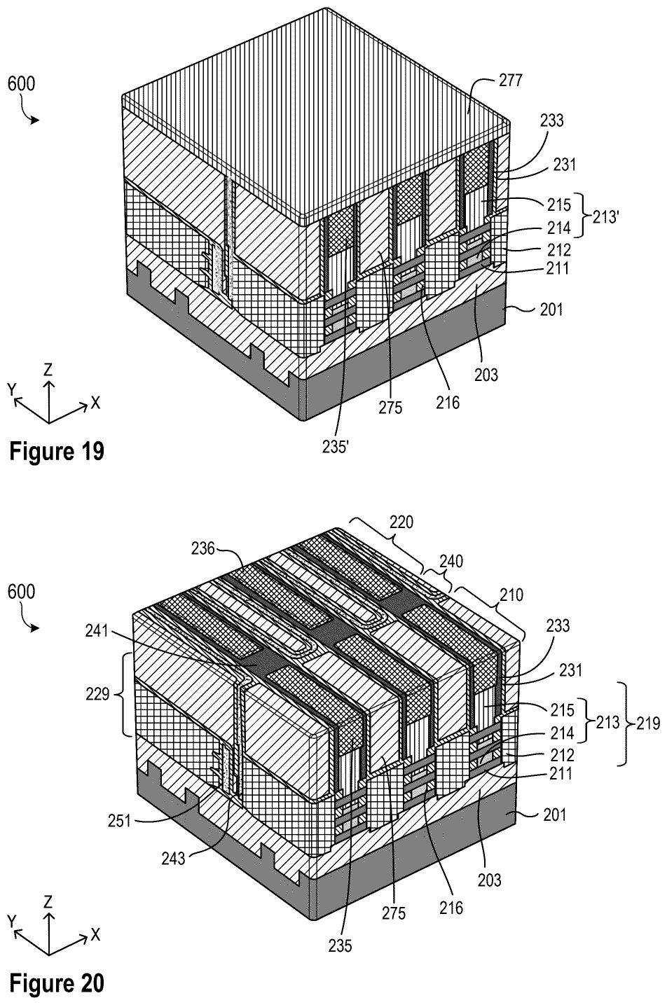

In FIG. 19, the dummy gate structures 261 are replaced with the gate structure 213′. For example, the sacrificial gate layers 262 and 263 can be removed before the gate dielectric 214 is formed, followed by formation of the gate metal 215. Therefore, the gate structures 213′ are formed. Gate contact 235′ is formed above the gate structures 213′. Subsequently, a hardmask layer 277 is formed on top.

In FIG. 20, the block structures 241 are formed to divide the gate structures 213′ into the first gate structures 213 in the first row 210 and second gate structures (not explicitly shown) in the second row 220. The gate contact 235′ is divided into the first gate contact structure 235 in the first row 210 and the second gate contact structure 236 in the second row 220. As a result, the first transistors 219 and the second transistors 229 are formed. Moreover, the isolation wall structure 240, which includes the slab structures 243 and the block structures 241 arranged alternatingly along the X direction, is formed.

In some embodiments, in order to form the block structures 241, a photoresist layer (not shown) can be used to etch the hardmask layer 277 which can then be used as an etching mask to etch the fin structures 260 to create holes (not shown). The holes are then filled with one or more dielectric materials which may be etched back or planarized to form the block structures 241.

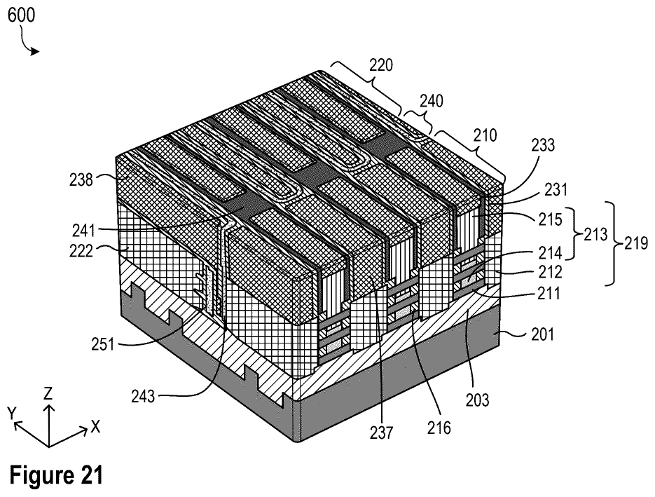

In FIG. 21, the dielectric material 275 is selectively removed to expose the dielectric material 231 that is disposed at least on sidewalls of the first gate structure 213 as well as on top surfaces of the first S/D structures 212. A directional and selective etching process (e.g. in the Z direction) can be executed to expose the top surfaces of the first S/D structures 212, similar to what is shown in FIGS. 6-8. The first S/D contact structure 237 and the second S/D contact structure 238 are respectively formed above the first S/D structures 212 and the second S/D structures 222, optionally followed by an etching or CMP process. Therefore, the semiconductor device 600 herein has become the semiconductor device 200 in FIGS. 2A and 2B.

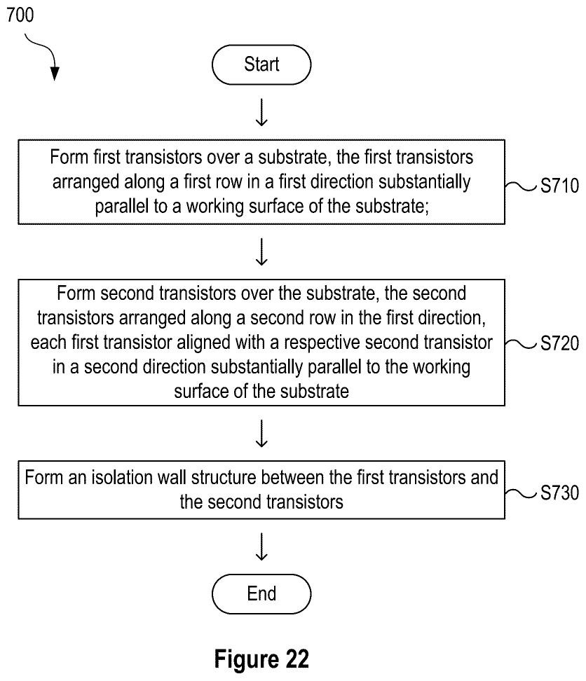

FIG. 22 shows a flow chart of a process 700 for manufacturing a semiconductor device (e.g. 100, 200 and the like), in accordance with some embodiments of the present disclosure. At step S710, first transistors are formed over a substrate. The first transistors are arranged along a first row in a first direction substantially parallel to a working surface of the substrate. At step S720, second transistors are formed over the substrate. The second transistors are arranged along a second row in the first direction. Each first transistor is aligned with a respective second transistor in a second direction substantially parallel to the working surface of the substrate. At step S730, an isolation wall structure is formed between the first transistors and the second transistors.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “wafer” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

The substrate can be any suitable substrate, such as a silicon (Si) substrate, a germanium (Ge) substrate, a silicon-germanium (SiGe) substrate, and/or a silicon-on-insulator (SOI) substrate. The substrate may include a semiconductor material, for example, a Group IV semiconductor, a Group III-V compound semiconductor, or a Group II-VI oxide semiconductor. The Group IV semiconductor may include Si, Ge, or SiGe. The substrate may be a bulk wafer or an epitaxial layer.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A semiconductor device, comprising:
first transistors positioned over a substrate and arranged along a first row in a first direction substantially parallel to a working surface of the substrate;
second transistors positioned over the substrate and arranged along a second row in the first direction, each first transistor aligned with a respective second transistor in a second direction substantially parallel to the working surface of the substrate; and
an isolation wall structure positioned between the first transistors and the second transistors.

2. The semiconductor device of claim 1, wherein:
the isolation wall structure includes slab structures and block structures arranged alternatingly along the first direction, and
the slab structures are thinner than the block structures in the second direction.

3. The semiconductor device of claim 2, wherein:
the slab structures consist of a first dielectric material.

4. The semiconductor device of claim 3, further comprising:
a second dielectric material formed on opposing sides of each of the slab structures as well as formed between gate contact structures of the first transistors and source/drain (S/D) contact structures of the first transistors.

5. The semiconductor device of claim 3, further comprising:
a sidewall structure consisting of the first dielectric material and positioned parallel to and away from the slab structures.

6. The semiconductor device of claim 2, wherein:
the slab structures are co-planar.

7. The semiconductor device of claim 2, wherein:
the slab structures are positioned between source/drain (S/D) structures of the first transistors and the second transistors, and
the block structures are positioned between gate structures of the first transistors and the second transistors.

8. The semiconductor device of claim 1, wherein:
the isolation wall structure consists of a dielectric material in a cross section substantially perpendicular to the working surface of the substrate.

9. The semiconductor device of claim 8, wherein:
the isolation wall structure is continuous and seamless in the cross section.

10. The semiconductor device of claim 8, wherein:
the cross section is substantially parallel to the first direction.

11. A method of manufacturing a semiconductor device, the method comprising:
forming first transistors over a substrate, the first transistors arranged along a first row in a first direction substantially parallel to a working surface of the substrate;
forming second transistors over the substrate, the second transistors arranged along a second row in the first direction, each first transistor aligned with a respective second transistor in a second direction substantially parallel to the working surface of the substrate; and
forming an isolation wall structure between the first transistors and the second transistors.

12. The method of claim 11, further comprising:
forming a row of transistors over the substrate, the row of transistors arranged in the first direction;
forming an opening to divide the row of transistors into the first transistors and the second transistors; and
forming the isolation wall structure in the opening.

13. The method of claim 12, wherein the row of transistors comprise channel structures, source/drain (S/D) structures and gate structures, the method further comprising:
forming an etch stop layer along sidewalls of the gate structure and on top surfaces of the S/D structures; and
filling remaining space of the etch stop layer with a dielectric material.

14. The method of claim 13, further comprising:
removing the dielectric material to expose the etch stop layer; and
directionally etching the etch stop layer to expose the top surfaces of the S/D structures.

15. The method of claim 14, further comprising:
forming S/D contact structures over the S/D structures.

16. The method of claim 11, further comprising:
forming fin structures over the substrate, the fin structures spaced apart from each other in the first direction and comprising channel structures and dummy gate structures; and
forming a dielectric material over the fin structures.

17. The method of claim 16, further comprising:
forming a protective structure over the fin structures in a first region while leaving the fin structures exposed in a second region;
isotropically forming a dielectric film over the protective structure in the first region and the fin structures in the second region, the dielectric film including vertical portions on sidewalls of the protective structure; and
directionally etching the dielectric film so that remaining vertical portions of the dielectric film include slab structures substantially perpendicular to the working surface of the substrate.

18. The method of claim 17, further comprising:
replacing the dummy gate structures with gate structures; and
forming block structures to divide the gate structures into first gate structures in the first row and second gate structures in the second row, the slab structures and the block structures arranged alternatingly along the first direction, wherein the slab structures are thinner than the block structures in the second direction.

19. The method of claim 18, further comprising:
directionally etching to expose top surfaces of the S/D structures; and
forming S/D contact structures over the S/D structures.

20. The method of claim 18, further comprising:
forming the dielectric material on opposing sides of the slab structures.
